(19) United States
(12) Patent Application Publication
(10) Pub. No.: US 2026/0255824 A1
(43) Pub. Date: Aug. 27, 2026

(54) DISPLAY APPARATUS AND DISPLAY PANEL

(71) Applicant: LG Display Co., Ltd., Seoul (KR)

(72) Inventors: Seung-Hyun LEE, Paju-si (KR); Jong-Moo HA, Paju-si (KR)

(73) Assignee: LG Display Co., Ltd., Seoul (KR)

(21) Appl. No.: 19/534,180

(22) Filed: Feb. 9, 2026

(30) Foreign Application Priority Data
Feb. 26, 2025 (KR) 10-2025-0025005

(51) Int. Cl. H10K 59/131; H10K 59/121; H10K 59/122; H10K 59/124; H10K 59/80

(52) U.S. Cl. CPC H10K 59/131; H10K 59/1213; H10K 59/122; H10K 59/124; H10K 59/873

(57) ABSTRACT

Disclosed are a display apparatus and a display panel. The display apparatus includes a substrate having a display area in which a plurality of sub-pixels are disposed to display an image, a hole formed in the display area in which an optical sensor is mounted, and a blocking unit formed between the display area and the hole. A thin film transistor and a light emitting device are disposed in each of sub-pixels. The blocking unit includes an opening, a first pattern disposed under the opening, and a second pattern disposed between the opening and the first pattern. The first pattern and the second pattern are configured to suppress damage to lower layers during formation of the opening and to restrict moisture penetration from the hole into the display area.

### CROSS-REFERENCE TO RELATED APPLICATION

This application claims priority and benefits of Korean Patent Application No. 10-2025-0025005, filed in the Republic of Korea on February 26, 2025, the entire contents of which are hereby expressly incorporated by reference into the present application.

### BACKGROUND

### Technical Field

The present disclosure relates to a display apparatus, and more particularly, for example, without limitation, to the display apparatus capable of preventing penetration of moisture.

### Description of the Related Art

As information technology develops, various types of small and thin display apparatuses such as a liquid crystal display apparatus, an organic light emitting display apparatus, a plasma display apparatus, a micro LED display apparatus, etc., have been proposed.

In this display apparatus, an optical device such as a camera is embedded therein to provide various functions to a user. A transmission hole is formed in the display apparatus to mount the optical device. However, in this case, moisture may penetrate from the transmission hole into the display area. When the organic light emitting device is exposed to moisture or oxygen, a pixel shrinkage phenomenon in which the emission area is reduced may occur, or a defect may occur in which a dark spot is generated in the emission area. Further, moisture may oxidize an electrode made of metal. Therefore, when moisture penetrates into the display area, defects may occur in the light emitting device and various electrodes.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### BRIEF SUMMARY

In view of the limitations of the related art, the present disclosure provides a display apparatus configured to suppress moisture penetration from a hole in which an optical sensor is mounted into a display area, by forming a blocking unit around the hole to interrupt moisture migration paths.

Another object of the present disclosure is to provide the display apparatus capable of preventing a defect in which a lower layer is etched when the opening is formed by forming first and second etch stopper layers on a lower portion of the opening.

In order to achieve the object, a display apparatus according the present disclosure comprising a substrate including a display area in which a plurality of sub-pixels to display an image, a hole formed in display area in which an optical sensor is mounted, and blocking unit formed between the display area and the hole, a thin film transistor and a light emitting device disposed in each of sub-pixels, an opening formed in the blocking unit, a first pattern disposed under the opening, and a second pattern disposed between the opening and the first pattern.

A bottom shielding metal layer is disposed on the substrate in the display area under the thin film transistor, and the first pattern is disposed on the substrate in the blocking unit. In this time, the first pattern is made of the same material as the bottom shielding metal layer.

The second pattern is disposed above the buffer layer, the second pattern is made of the same material as the semiconductor layer.

A metal pattern is disposed on the passivation layer in the blocking unit, and the metal pattern is protruded toward the opening to form an overhang structure with the opening. At this time, the metal pattern is made of the same material as the source electrode and the drain electrode.

An insulating pattern is disposed under the metal pattern within the opening to cover both sides of the opening. At this time, the insulating pattern is made of the same material as the first planarization layer.

In order to achieve the object, a display panel according the present disclosure comprising a substrate including a display area in which a plurality of sub-pixels to display an image, a hole formed in display area in which an optical sensor is mounted, and blocking unit formed between the display area and the hole, a thin film transistor and a light emitting device disposed in each of sub-pixels, an opening formed in the blocking unit, a first pattern disposed under the opening, and a second pattern disposed between the opening and the first pattern.

The effects of the present disclosure are not limited to the aforementioned effects, and other effects, which are not mentioned above, will be apparently understood to a person having ordinary skill in the art from the following description.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure.

FIG. 1 is a schematic block diagram of a display apparatus according to the present disclosure.

FIG. 2 is the schematic block diagram of a sub-pixel of FIG. 1.

FIG. 3 is a circuit diagram conceptually showing the sub-pixel of the display apparatus according to the present disclosure.

FIG. 4 is an exploded perspective view schematically illustrating the display apparatus according to the present disclosure.

FIG. 5 is a schematic plan view illustrating a display panel of the display apparatus according to the present disclosure.

FIG. 6 is a partially enlarged plan view of the sensor area of FIG. 5.

FIG. 7 is a cross-sectional view taken along line I-Iʹ of FIG. 6.

FIG. 8 is an enlarged cross-sectional view of area A of FIG. 7.

FIGS. 9A to 9I are views illustrating a method of manufacturing the display apparatus according to the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and features of the present disclosure and methods for achieving them will be made clear from example embodiments described below in detail with reference to the accompanying drawings. The present disclosure may, however, be implemented in many different forms and should not be construed as being limited to the example embodiments set forth herein. The example embodiments are provided such that this disclosure will be more thorough and complete and will more fully convey the scope of the present disclosure to those skilled in the art to which the present disclosure pertains. A protected scope of the present disclosure may be defined by the scope of the appended claims and their equivalents.

The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Shapes, sizes, dimensions (e.g., length, width, height, thickness, radius, diameter, area, etc.), ratios, angles, numbers of elements, and the like disclosed in the drawings for describing the example embodiments of the present disclosure are illustrative, and thus the present disclosure is not limited to the illustrated examples.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure, unless otherwise specified. Further, in the following description of the present disclosure, where a detailed description of a known related art may unnecessarily obscure a feature or aspect of the present disclosure, the detailed description of such known related art may be omitted herein.

Where terms such as “include,” “have,” “comprise,” “contain,” “constitute,” “make up of,” “formed of,” and “consist of” and the like are used in this disclosure, other parts may be added unless a more specific term like “only” is used herein. Where a component is expressed as being singular, being plural is included unless otherwise specified.

In analyzing a component, an error range is to be interpreted as being included even where there is no explicit description.

In a description of a positional relationship, for example, where a positional relationship of two parts is described as being “on,” “above,” “over,” “below,” “under,” “beside,” “beneath,” “near,” “close to,” “adjacent to,” “on a side of,” “next” or the like, one or more other parts may be located between the two parts unless a more specific term like “immediately” or “directly” is used.

Spatially relative terms, such as “under,” “below,” “beneath,” “lower,” “over,” “upper” and the like, may be used herein for ease of description to describe one element or feature’s relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below.”

In a description of a temporal relationship, for example, where a temporal predecessor relationship is described as being “after,” “subsequent,” “next to,” “prior to,” or the like, cases that are not continuous or consecutive may also be included unless a more specific term like “immediately” or “directly” is used.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

Although such terms as first, second, and the like may be used to describe various components, these components are not substantially limited by these terms. These terms are used only to refer to one component separately from another component. Therefore, a first component described below may substantially be a second component, and vice versa, within the technical spirit of the present disclosure.

In describing the components of the disclosure, terms such as first, second, A, B, (a), (b), etc., may be used. These terms are only for referring to the elements separately from other elements, and the essence, order, or number of the elements is not limited by the terms. Where a component is described as being “coupled” or “connected” to another component, the component may be directly or indirectly coupled or connected to the other component, unless a more specific term like “directly” is used. It should be understood that one or more other components may be “interposed” and connected between the components that are “coupled” or “connected” to each other.

The word “exemplary” is used to mean serving as an example or illustration. Aspects are example aspects. “Embodiments,” “examples,” “aspects,” and the like should not be construed as preferred or advantageous over other implementations. An embodiment, an example, an exemplary embodiment, an aspect, or the like may refer to one or more embodiments, one or more examples, one or more example embodiments, one or more aspects, or the like, unless stated otherwise. Further, the term “may” encompasses all the meanings of the term “can.”

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

As used herein, the term “apparatus” may refer to a display apparatus such as a liquid crystal module (LCM) or an organic light emitting display module (OLED module) that includes a display panel and a driving unit (or a driving circuit) for driving the display panel. Further, the term “apparatus” may refer to a notebook computer, a television, a computer monitor, a vehicle electric apparatus including an apparatus for a vehicle or other type of vehicle, or a set electronic apparatus or a set apparatus, such as a mobile electronic apparatus of a smart phone, an electronic pad, or the like, which is a finished product (a complete product or a final product) including an LCM or an OLED module.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the specification, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

Accordingly, the apparatus in the present disclosure may encompass a display apparatus itself, such as the LCM, the OLED module, etc., and an apparatus for end users like an application product or a set apparatus that includes the LCM, the OLED module, or the like.

The disclosed subject matter relates to a display apparatus in which a sensor hole is formed within the display area and is surrounded by a dedicated blocking unit configured to limit moisture penetration into the active region. Unlike approaches that rely on notches or edge cutouts, the hole is fully embedded within the display area, which introduces a direct moisture ingress path. This path is addressed by forming a blocking structure with openings arranged around the hole, thereby protecting thin film transistors, electrodes, and light emitting layers from degradation caused by moisture and oxygen.

The blocking unit includes a layered structure beneath each opening that functions to control etching and suppress damage to lower layers. A first pattern is disposed on the substrate and a second pattern is disposed above the buffer layer, with each pattern formed using materials already present in the thin film transistor stack, namely the bottom shielding metal layer and the semiconductor layer. By vertically stacking these patterns and defining width relationships between the patterns and the openings, over etching of the buffer layer and substrate is suppressed and alignment tolerance during fabrication is improved, which in turn reduces defect generation and moisture diffusion.

Further, each opening is configured with a three dimensional barrier structure that includes a metal pattern protruding over the opening and an insulating pattern remaining along the sidewalls of the opening. The metal pattern and insulating pattern cooperate to lengthen the moisture diffusion path and to block lateral moisture migration along organic planarization layers. This structure is formed using existing deposition and photolithography processes, including partial exposure techniques, and provides an integrated solution that addresses both moisture ingress through the sensor hole and process induced damage during opening formation.

Hereinafter, various example embodiments of the present disclosure will be described in detail with reference to the accompanying drawings.

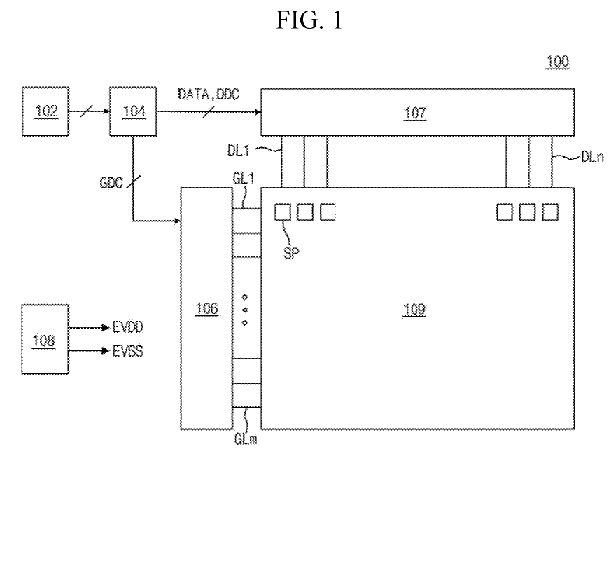

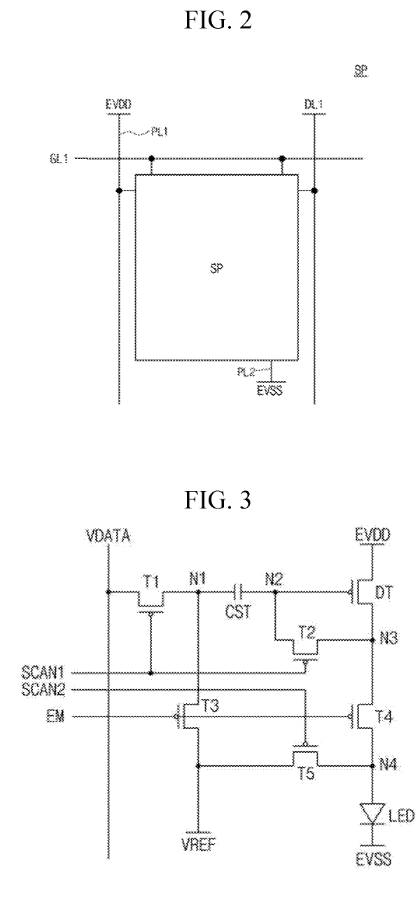

FIG. 1 is a schematic block diagram of a display apparatus according to one or more example embodiments of the present disclosure, and FIG. 2 is the schematic block diagram of a sub-pixel SP of an organic light emitting display apparatus according to one or more example embodiments of the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving 107 may be mounted on the upper surface of the display panel 109 in the form of an integrated circuit (IC), but is not limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas. However, the present disclosure is not limited thereto. A plurality of subpixels SP constituting unit pixel may be variously modified in colors and configurations, as necessary.

For example, each of the plurality of subpixels SP may emit light having different wavelengths from each other. For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

As shown in FIG. 2, one sub-pixel SP may be connected to a gate line GL1, a data line DL1, a first power line PL1, and a second power line PL2. The number of transistors and capacitors as well as a driving method of the sub-pixel SP are determined according to the configuration of the pixel circuit.

FIG. 3 is the circuit diagram illustrating the sub-pixel SP of the organic light emitting display apparatus 100 according to the present disclosure. Although one sub-pixel SP includes six transistors and one capacitor (6T1C) in the drawing, this is exemplary, and the number of transistors and capacitors constituting the pixel circuit is not limited thereto. Each of the subpixels may further include a compensation circuit. In this case, various structures such as 4T2C, 5T2C, 6T2C, 7T1C, 7T2C, and the like may be provided.

As shown in FIG. 3, one sub-pixel SP includes a first transistor T1, a second transistor T2, a third transistor T3, a fourth transistor T4, a fifth transistor T5, a driving transistor DT, a storage capacitor CST, and a light emitting device LED.

The light emitting device LED emits light by a driving current supplied from the driving transistor DT. The anode of the light emitting device LED is connected to the fourth node N4, and the cathode of the light emitting device LED is connected to the input terminal of the low potential voltage EVSS.

The driving transistor DT controls the driving current applied to the light emitting device LED according to the voltage between the source electrode and the gate electrode. The source electrode of the driving transistor DT is connected to the input terminal of the high potential voltage EVDD, the gate electrode is connected to the second node N2, and the drain electrode is connected to the third node N3.

The first transistor T1 includes a gate electrode connected to an input terminal of the first scan signal SCAN1, a source electrode connected to a data line for supplying a data voltage VDATA, and a drain electrode connected to a first node N1. The first transistor T1 may apply the data voltage VDATA supplied from the data line DL to the first node N1 in response to the first scan signal SCAN1.

The second transistor T2 includes a source electrode connected to the third node N3, a drain electrode connected to the second node N2, and a gate electrode connected to the input terminal of the first scan signal SCAN1. The second transistor T2 may diode-connect the gate electrode and the drain electrode of the driving transistor DT in response to the first scan signal SCAN1.

The third transistor T3 includes a gate electrode connected to the input terminal of the light emitting signal, a source electrode connected to the first node N1, and a drain electrode connected to the input terminal of the reference voltage VREF. The third transistor T3 may apply the reference voltage VREF to the first node N1 in response to the light emitting signal EM.

The fourth transistor T4 includes a source electrode connected to the third node N3, a drain electrode connected to the fourth node N4, and a gate electrode connected to the input terminal of the light emitting signal EM. The fourth transistor T4 forms a current path between the third node N3 and the fourth node N4 in response to the light emitting signal EM.

The fifth transistor T5 includes a drain electrode connected to the fourth node N4, a source electrode connected to the input terminal of the reference voltage VREF, and a gate electrode connected to the input terminal of the second scan signal SCAN2. The fifth transistor T5 may apply the reference voltage Vref to the fourth node N4 in response to the second scan signal SCAN2.

The storage capacitor CST includes a first electrode connected to the first node N1 and a second electrode connected to the second node N2.

Meanwhile, each of transistors above may be a thin-film transistor. An active layer of the thin-film transistor may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Hereinafter, the display apparatus according to an embodiment of the present disclosure will be described in detail with reference to the accompanying drawings.

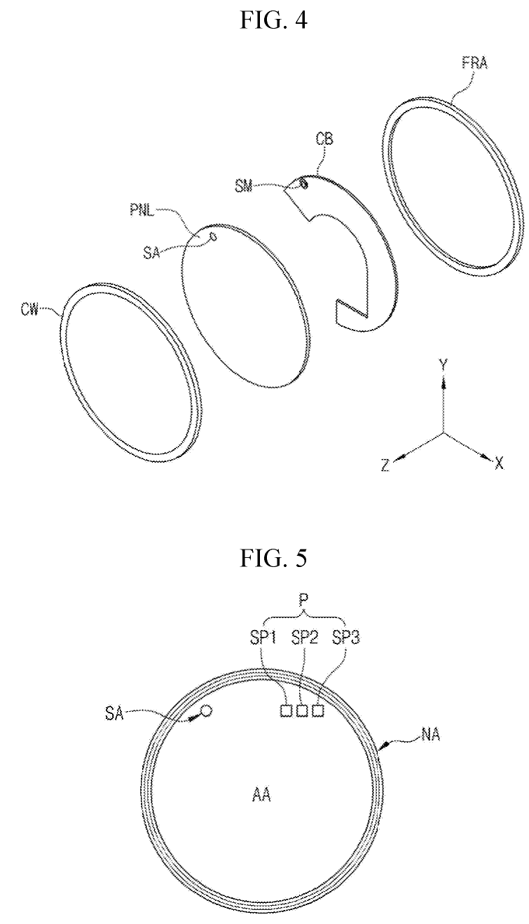

FIG. 4 is an exploded perspective view schematically illustrating a display apparatus 100 according to the embodiment of the present disclosure, and FIG. 5 is a schematic plan view illustrating a display panel PNL of the display apparatus 100 according to the embodiment of the present disclosure.

The display apparatus 100 of the present disclosure may be applied to various electronic devices. For example, the display apparatus 100 of the present disclosure may be applied to a mobile device such as a smartphone or a wearable device such as a watch. Hereinafter, the display apparatus 100 applied to the watch is described as an example, but is not limited thereto.

As shown in FIG. 4, the display apparatus 100 according to the embodiment of the present disclosure includes a display panel PNL, a sensor module SM, a circuit board CB, a cover window CW, and a frame FRA.

The display panel PNL includes a display area AA in which an image is displayed and a non-display area NA disposed outside the display area AA. The non-display area NA is an area where an image is not displayed, and may be defined in an edge portion of the display panel PNL to surround a portion or the entirety of the display area AA. The non-display area NA may be an area adjacent to the display area AA. Further, the non-display area NA may be an area disposed adjacent to the display area AA and configured to surround the display area AA. However, the present disclosure is not limited thereto.

For example, the non-display area NA may include a first non-display area located outside the display area AA in a first direction, a second non-display area located outside the display area AA in a second direction intersecting the first direction, a third non-display area located outside the display area AA in the opposite direction to the first direction, and a fourth non-display area located outside the display area AA in the direction opposite to the second direction.

For another example, a boundary area between the display area AA and the non-display area NA may be bent so that the non-display area NA may be located below the display area. In this case, when the user looks at the display apparatus from the front, there may be little or no non-display area NA visible to the user.

A pixel P including a plurality of sub-pixels SP1, SP2, and SP3 is arranged in the display area AA. At this time, each of the sub-pixels SP1, SP2, and SP3 may include each of a red (R) sub-pixel, a green (G) sub-pixel, and a blue (B) sub-pixel. In addition, the pixel P may further include a white (W) sub-pixel.

Although not shown in the figure, a plurality of gate lines and data lines are arranged in the display area AA to define a plurality of sub-pixels SP in the intersection area of the gate lines and data lines. In each sub-pixel SP1, SP2, and SP3, a thin film transistor as a switching device and a display device for displaying an image are arranged.

The display device may include various display devices. For example, the display device may be an organic light emitting display device, a liquid crystal display device, a quantum dot display device, a micro LED display device, or a mini LED display device.

The gate driving unit 106 and the data driving unit 107 for supplying various signals to sub-pixels SP1, SP2, and SP3 can be disposed in the non-display area NA. The gate driving unit 106 applies the scan signal to the sub-pixels SP1, SP2, and SP3 through the gate line, and the data driving unit 107 applies the image signal to the sub-pixels SP1, SP2, and SP3 through the data line. At this time, the gate driving unit is a Gate-In-Panel that includes gate driving circuits.

The sensor module SM may be disposed on the rear surface of the display panel PNL. The sensor module SM may be overlapped with the display area AA of the display panel PNL. The sensor module SM may mean all elements using an external input through the display panel PNL. For example, the sensor module SM may be an optical sensor such as a camera, an illuminance sensor, a fingerprint sensor, and IR(Infrared) sensor, etc.

The sensor module SM according to the present disclosure is disposed under the display area AA of the display panel PNL.

In conventional display apparatus, after forming a notch at the upper end of the display area AA, the optical sensor such as the camera or the IR sensor is disposed at the notch. However, in this case, since the notch is formed by removing a part of the upper end of the display area AA, there is a problem that the size of the display area AA is reduced, and the beauty is not good.

In the present disclosure, since a hole is formed in the display area AA and the optical sensor is disposed in the hole, it is possible to solve the problem that the size of the display area AA is reduced and the beauty is not good.

The circuit board CB may be disposed on the rear surface of the display panel PNL. The circuit board CB may include a printed circuit board (PCB) or a flexible printed circuit board (FPCB).

The cover window CW may be disposed on the front surface of the display panel PNL. The cover window 400 may cover the front surface of the display panel PNL to protect the display panel PNL from an external impact.

The cover window CW may be formed of a transparent plastic material, a glass material, or a tempered glass material, but is not limited thereto. For example, the cover window CW may be made of any one of sapphire glass and gorilla glass, or may be formed as a stacked structure thereof. Further, the cover window CW may be made of any one of PET (polyethylene terephthalate), PC (polycarbonate), PES (polyether sulfone), PEN (polyethylene naphthalate), and PNB (polynorbornene). The cover window CW may be made of tempered glass in consideration of scratches and transparency.

The frame FRA accommodates the display panel PNL and supports the cover window CW. The sensor module SM and the circuit board CB are disposed inside the frame FRA. The frame FRA fixes the display panel PNL, the sensor module SM, and the circuit board CB to the display apparatus 100 and protects them from external impact.

The frame FRA accommodates the display panel PNL and supports the cover window CW. The frame FRA accommodates the sensor module SM and the circuit board CB. The frame FRA fixes the display panel PNL, the sensor module SM, and the circuit board CB to the display apparatus 100 and protects them from external impact.

In this case, the sensor area SA may be formed in various positions of the display area AA. In the drawing, the sensor area SA is formed near the circumference of the display area AA, but the sensor area SA may be formed near the center of the display area AA.

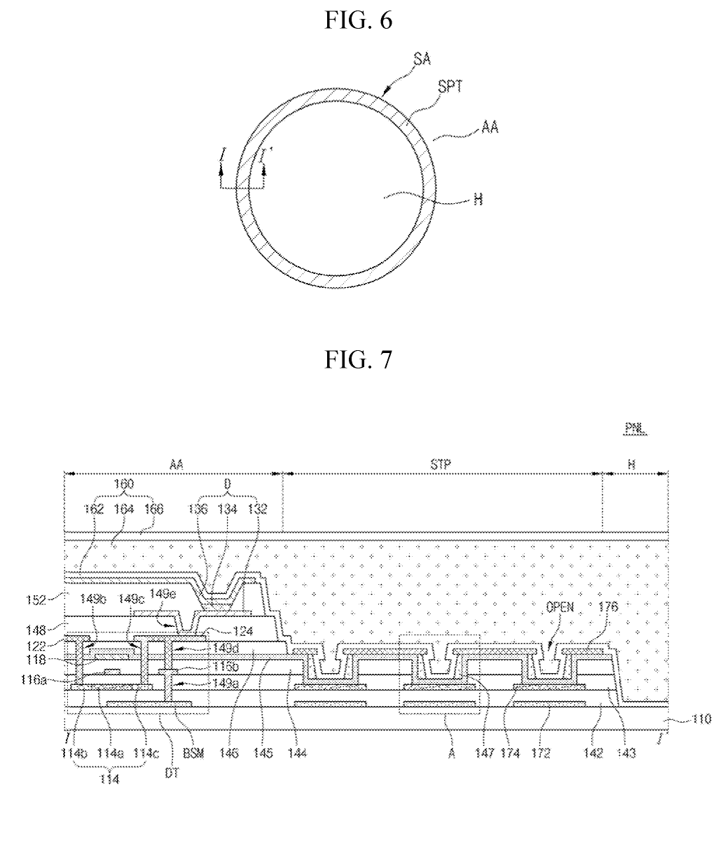

FIG. 6 is a partially enlarged plan view of the sensor area SA of FIG. 5. As shown in FIG. 6, a hole H is formed in the sensing area SA. The hole H is formed to correspond to the sensor module SM so that the light transmitted through the hole H reaches the sensing module SM. As will be described later, the hole H may be formed by removing various structures disposed in the display area AA. For example, the hole H may be formed by removing various insulating layers disposed in the display area AA.

In the drawing, the hole H is formed in a circular shape, but is not limited thereto, and the hole H may be formed in various shapes. For example, the hole H may be formed in the shape such as an elliptical shape or a polygonal shape. Further, the hole H may be formed in the same shape as the shape of the corresponding sensor module SM.

A blocking unit STP is formed around the hole H. Since the hole H is formed by removing various insulating layers of the display area AA, the hole H is directly exposed to an external environment. Therefore, moisture may penetrate into the display area AA through the inner surface of the hole H. Moisture not only causes oxidation of various electrodes and signal lines, but also causes deterioration of the organic light emitting layer.

The blocking unit STP is formed along the periphery of the hole H to block moisture penetrating into the display area AA through the inner surface of the hole H to prevent oxidation of various electrodes and signal lines and deterioration of the organic light emitting layer.

In the drawing, the blocking unit STP is formed continuously along the periphery of the hole H in a closed curve shape, but the blocking unit STP may be formed discontinuously along the periphery of the hole H.

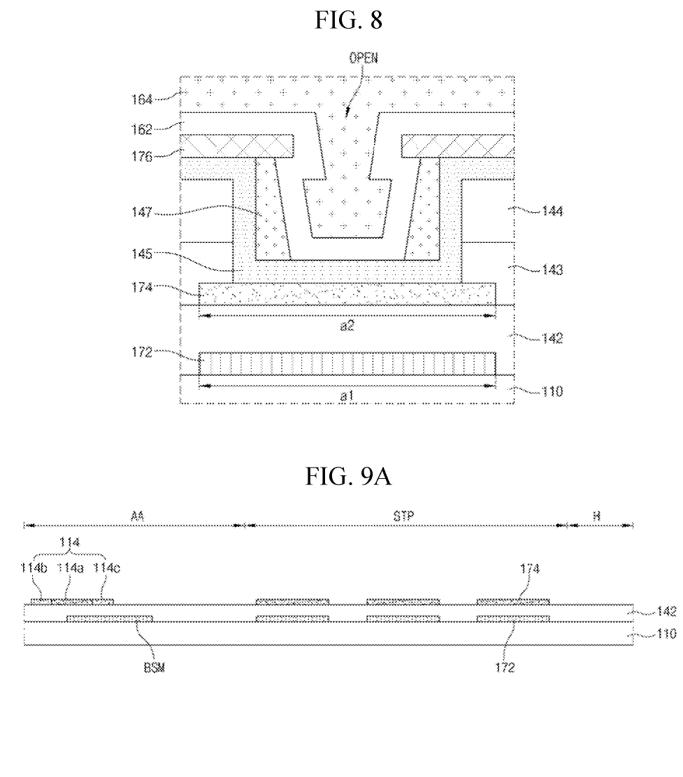

FIG. 7 is a cross-sectional view taken along the line I-I′ of FIG. 6, and FIG. 8 is an enlarged cross-sectional view of the area A of FIG. 7. Although 1-5th transistors T1-T5 and the driving transistor DT are disposed on the actual display panel PNL, only the driving transistor DT is shown for convenience of description, and other transistors are omitted.

As shown in FIGS. 7 and 8, the substrate 110 includes the display area AA, the blocking unit STP, and the hole H.

The substrate 110 may be made of a hard material such as glass. Further, the substrate 110 may be made of the plastic material such as a polyimide, a polymethylmethacrylate, a polyethylene tereththalate, a Polyethersulfone, and a Polycarbonate, but is not limited thereto.

When the substrate 110 is made of polyimide, the substrate 110 may be made of a plurality of polyimide layers, and an inorganic layer may be further disposed between the polyimide layers, for example, a silicon oxide (SiOx) layer or a silicon nitride (SiNx) layer may be further disposed between the polyimide layers, but is not limited thereto.

A bottom shield metal layer BSM is disposed in the display area AA on the substrate 110. The bottom shield metal layer BSM minimizes a backchannel phenomenon caused by charges trapped in the substrate 110 to prevent afterimages or deterioration of transistor performance. The bottom shield metal layer BSM may be made of a metal, but is not limited thereto.

A plurality of first patterns 172 are disposed on the blocking unit STP on the substrate 110. The first pattern 172 may be formed of the same material (e.g., metal) as the bottom shield metal layer BSM, but may be formed of a different material. A plurality of first patterns 172 are formed to be spaced apart from each other by a predetermined distance and are disposed continuously or discontinuously along the periphery of the hole H.

A buffer layer 142 is formed on the substrate 110 on which the bottom shield metal layer BSM and the first patterns 172 are formed. The buffer layer 142 may be formed in the entire area of the substrate 110 to enhance adhering force between the substrate 110 and the layers thereon. Further, the buffer layer 142 may block various types of defects, such as alkali components flowing out from the substrate 110. In addition, the buffer layer 142 may delay diffusion of moisture or oxygen penetrating into the substrate 110.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 110, the structure and type of the thin film transistor, and the like.

A thin film transistor is formed on the buffer layer in the display area AA. The transistor DT includes a semiconductor layer 114, a gate electrode 116a, a source electrode 122, and a drain electrode 124.

The semiconductor layer 114 is formed on the buffer layer 142, and a gate insulating layer 143 is formed on the semiconductor layer 114 and the buffer layer 142.

The semiconductor pattern 114 may be made of an oxide semiconductor. For example, semiconductor pattern 114 may be made of one of IGZO (Indium-gallium-zinc-oxide), IZO (Indium-zinc-oxide), IGTO (Indium-gallium-tin-oxide), and IGO (Indium-gallium-oxide), but is not limited thereto.

Further, the semiconductor pattern 114 may be made of a polycrystalline semiconductor. For example, the polycrystalline semiconductor may be made of low temperature poly silicon (LTPS) having high mobility, but is not limited thereto.

The semiconductor pattern 114 includes a channel region 114a in a central region and a source region 114b and a drain region 114c which are doped layers at the both sides of the channel region 114a.

A plurality of second patterns 174 are disposed on the buffer layer 142 of the blocking unit STP. The second pattern 174 is aligned with the first pattern 172 with the buffer layer 142 interposed therebetween. In the drawing, the width a1 of the first pattern 172 is the same as the width a2 of the second pattern 174 (a1=a2), but the width a1 of the first pattern 172 may be greater than the width a2 of the second pattern 174 (a1>a2). As the width a1 of the first pattern 172 is greater than the width a2 of the second pattern 174, the misalignment of the first pattern 172 and the second pattern 174 may be prevented due to a process error.

Like the first pattern 172, a plurality of second patterns 174 are formed to be spaced apart from each other by a predetermined distance and are disposed continuously or discontinuously along the periphery of the hole H.

A gate insulating layer 143 is formed on the semiconductor layer 114. The gate insulating layer 143 may be formed of the single layer or the multiple layers made of an inorganic material such as SiOx or SiNx. For example, the gate insulating layer 143 may be formed as a single layer of any one of a silicon oxide (SiOx) film, a silicon nitride (SiNx) film, and a silicon oxynitride (SiON) film, or a multilayer thereof. For example, the gate insulating layer 143 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The gate electrode 116a is disposed on the gate insulating layer 143. Further, the connection electrode 116b is disposed on the gate insulating layer 143. The interlayer insulating layer 144 is formed on the gate electrode 116a and the connection electrode 116b. The gate electrode 116a and the connection electrode 116b may be made of the same metal in the same process, but are not limited thereto, and may be made of different metals by different processes.

The gate electrode 116a and the connection electrode 116b are made of metal. For example, the gate electrode 116a and the connection electrode 116b may be formed of the single layer or the multiple layers made of any one of molybdenum (Mo), aluminum (Al), chromium (Cr), gold (Au), titanium (Ti), nickel (Ni), neodymium (Nd), and copper (Cu), or alloy thereof, but are not limited thereto.

The interlayer insulating layer 144 may be made of the organic material such as photo-acryl, or the interlayer insulating layer 144 may formed of the single layer or the multiple layers made of the inorganic material such as SiOx or SiNx. For example, the interlayer insulating layer 144 may be formed as a single layer of any one of a silicon oxide (SiOx) film, a silicon nitride (SiNx) film, and a silicon oxynitride (SiON) film, or a multilayer thereof. For example, the interlayer insulating layer 144 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. Further, the interlayer insulating layer 146 may be formed of the multi layers of the organic material layer and the inorganic material layer, but is not limited thereto.

The connection electrode 116b is electrically connected to the bottom shielding metal layer BSM through the first contact hole 149a formed in the buffer layer 142 and the gate insulating layer 143.

A storage electrode 118 is disposed in the display area AA on the interlayer insulating layer 144. The storage electrode 118 may be made of metal, but is not limited thereto. The storage electrode 118 may form a storage capacitor with the gate electrode 116a. The storage electrode 118 may be formed of the single layer or the multiple layers made of any one of molybdenum (Mo), aluminum (Al), chromium (Cr), gold (Au), titanium (Ti), nickel (Ni), neodymium (Nd), and copper (Cu), or alloy thereof, but are not limited thereto. Meanwhile, the storage electrode 118 and the gate electrode 116a may be formed of a same or different material.

A passivation layer 145 is formed on the interlayer insulating layer 144 in which the storage electrode 118 is formed. The passivation layer 145 may be made of the inorganic material such as SiNx or SiOx.

A first planarization layer 146 is formed on the passivation layer 145, and a source electrode 122 and a drain electrode 124 are formed in the display area AA on the first planarization layer 146.

The first planarization layer 146 may be made of the organic material such as photoacrylic, but may be formed of the multiple layers made of the inorganic material and the organic material.

The source electrode 122 and the drain electrode 124 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 122 and the drain electrode 124 are ohmic-contacted with the source region 114b and the drain region 114c of the semiconductor layer 114 through the second contact hole 149b and the third contact hole 149c formed in the gate insulating layer 143, the interlayer insulating layer 144, and the first planarization layer 146, respectively. Further, the drain electrode 124 is electrically connected to the connection electrode 116b through the fourth contact hole 149d.

A second planarization layer 148 is formed on the thin film transistor DT. The second planarization layer 148 may be made of the organic material such as photoacrylic, but is not limited thereto and may be formed of the multiple layers made of the inorganic layer and the organic layer. Further, the second planarization layer 148 may be formed of the same material as the first planarization layer 146, but may also be formed of a different material.

An opening OPEN is formed on each of a plurality of second patterns 174 of the blocking unit STP. A plurality of openings OPEN may be formed to be spaced apart from each other by a predetermined distance and may be formed continuously or discontinuously along the periphery of the hole H.

Each of a plurality of openings OPEN may be formed by removing the gate insulating layer 143 and the interlayer insulating layer 144. Since the width a3 of the opening OPEN is smaller than the width a2 of the second pattern 174, the second pattern 174 is exposed to the outside through the opening OPEN.

The passivation layer 145 formed in the blocking unit STP extends inside the opening OPEN and is disposed on the sidewall of the gate insulating layer 143 and the interlayer insulating layer 144 of the opening OPEN and the upper surface of the second pattern 174 exposed to the outside by the opening OPEN.

The metal pattern 176 is disposed on the passivation layer 145 formed in the blocking unit STP. In this case, the metal pattern 176 extends to the inside of the opening OPEN so that the metal pattern 176 and the opening OPEN form an overhang structure. For example, the metal pattern 176 protrudes in a direction towards the inside of the opening OPEN compared to the passivation layer 145 disposed below the metal pattern 176 and being in contact with the metal pattern 176, but not limited thereto. The metal pattern 176 may be made of the same metal as the source electrode 122 and the drain electrode 124, or may be made of the different metal.

An insulating pattern 147 is formed in the opening OPEN under the metal pattern 176 forming the overhang structure. The insulating pattern 147 is formed to cover the sidewalls of the opening OPEN, and the width of the insulating pattern 147 increases from the lower surface of the metal pattern 176 to the upper surface of the passivation layer 145 on the bottom of the opening OPEN. However, the width of the insulating pattern 147 disposed on the upper surface of the passivation layer 145 on the bottom of the opening OPEN is smaller than the length of the metal pattern 176 protruding from the opening OPEN. The metal pattern 176 may be made of the same material as the first planarization layer 146, but is not limited thereto.

Each of the gate insulating layer 143 and the interlayer insulating layer 144 is disconnected by the plurality of openings OPEN, so that the penetration of the moisture to the display area AA through the gate insulating layer 143 and the interlayer insulating layer 144 may be prevented. As a result, the oxidation of various signal lines and electrodes and deterioration of the light emitting layer due to the moisture may be prevented.

The light emitting device D is disposed in the display area AA on the second planarization layer 148. The light emitting device D includes a first electrode 132, a light emitting layer 134, and a second electrode 136.

The first electrode 132 is disposed on the second planarization layer 148 and electrically connected to the drain electrode 124 of the thin film transistor DT through the fifth contact hole 149e formed in the second planarization layer 148.

The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO), but not limited thereto.

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer 152 is formed at the boundary between the sub-pixels on the second planarization layer 148. The bank layer 152 may be a barrier wall to define sub-pixels. The bank layer BNK divides each sub-pixel to prevent light of a specific color output from adjacent sub-pixels from being mixed and output.

The bank layer 152 is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

Meanwhile, the bank layer 152 may include a first bank layer and a second bank layer overlapping with each other. The first bank layer may be made of an opaque material (e.g., black material) to suppress the optical interference between adjacent sub-pixels. The second bank layer may be made of a transparent material. The first bank layer and the second bank layer may include, but is not limited to, a light-shielding material made of at least one of a color pigment, an organic black material, and carbon.

Meanwhile, the first bank layer and the second bank layer may be formed as separate configurations, but may also be formed integrally to form one bank layer. That is, the first bank layer and the second bank layer may be integrated as one bank layer and implemented.

The first bank layer and the second bank layer may be disposed at a boundary between the plurality of subpixels SP and suppress a color mixture of light beams from the plurality of subpixels SP.

Although not shown in the drawings, a spacer may be disposed on the bank layer 152. When the light emitting layer 134 is formed by depositing an organic light emitting material, the metal mask is positioned on the spacer to separate the metal mask from the object to be deposited by a predetermined distance. Thus, when the light emitting layer 134 is formed in a different method, the spacer may be omitted.

The light emitting layer 134 may be formed in R, G, and B sub-pixels and include an R-light emitting layer for emitting red light, a G-light emitting layer for emitting green light, and a B-light emitting layer for emitting blue light. For example, the light emitting layer 134 may be the organic light emitting layer, an inorganic light emitting layer, a nano-sized material layer, a quantum dot layer, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

When the display apparatus 100 is the top emission type, the second electrode 136 may be made of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 188 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 160 is formed in the display area AA and the blocking unit STP to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D oxidizes the metal electrode. The encapsulation layer 160 blocks impurities such as oxygen and moisture from the outside to prevent defects of the light emitting device D and various electrodes.

The encapsulation layer 160 may be formed of a first encapsulation layers 162, a second encapsulation layer 164, and a third encapsulation layer 166, but is not limited thereto. The encapsulation layer 160 may be formed of two layers or four or more layers.

For example, the encapsulation layer 160 has a structure in which inorganic encapsulation layers and organic encapsulation layers are alternately stacked, such that the encapsulation layer 160 may protect the light-emitting element while inhibiting moisture or oxygen from penetrating into the light-emitting element. For example, the encapsulation layer 160 may have a multi-insulating film structure in which organic films and inorganic films are stacked alternately. The inorganic film can block permeation of moisture or oxygen. The organic film may planarize a surface of the inorganic film. When the organic film and the inorganic film are stacked in multiple layers, a movement path of moisture or oxygen may be longer than that of a single layer, thereby effectively blocking the permeation of moisture and oxygen affecting the light emitting layer.

The first encapsulation layer 162 and the third encapsulation layer 166 may be formed of the single layer of the inorganic material such as SiOx, SiON, SiNx or the like, or the multi layers including the same, and may further include the organic material between inorganic materials, and the present disclosure is not limited thereto. The second encapsulation layer 164 may be formed of an epoxy resin.

Alternatively, the encapsulation layer 160 includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Although not shown in figure, a touch member may be disposed on the encapsulating layer 180. The touch member can detect external touch information using the user’s finger or a touch pen.

The hole H is formed by removing the buffer layer 142, the gate insulating layer 143, the interlayer insulating layer 144, the passivation layer 145, and the first and second planarization layers 146 and 148, and the encapsulation layer 160 is formed in the hole H.

As described above, in the display apparatus 100 according to the present disclosure, by forming the blocking unit STP including a plurality of openings OPEN around the hole H, the moisture penetrating along the first planarization layer 146 made of organic material through the hole H is blocked, so that the various electrodes and the signal lines are not oxidized and the light emitting layer is not deteriorated.

Meanwhile, since the first pattern 172 and the second pattern 174 disposed under the opening OPEN prevent the etching of the buffer layer 142 when the opening OPEN is formed, the defect due to penetration of various types of impurities from the substrate 110 or the defect due to diffusion of moisture or oxygen penetrating into the substrate 110 may be prevented. In this regard, the first pattern 172 and the second pattern 174 may be referred to as a first etch stop pattern and a second etch stop pattern, respectively.

Hereinafter, etching of the lower layer is prevented when the opening OPEN is formed by the first pattern 172 and the second pattern 174.

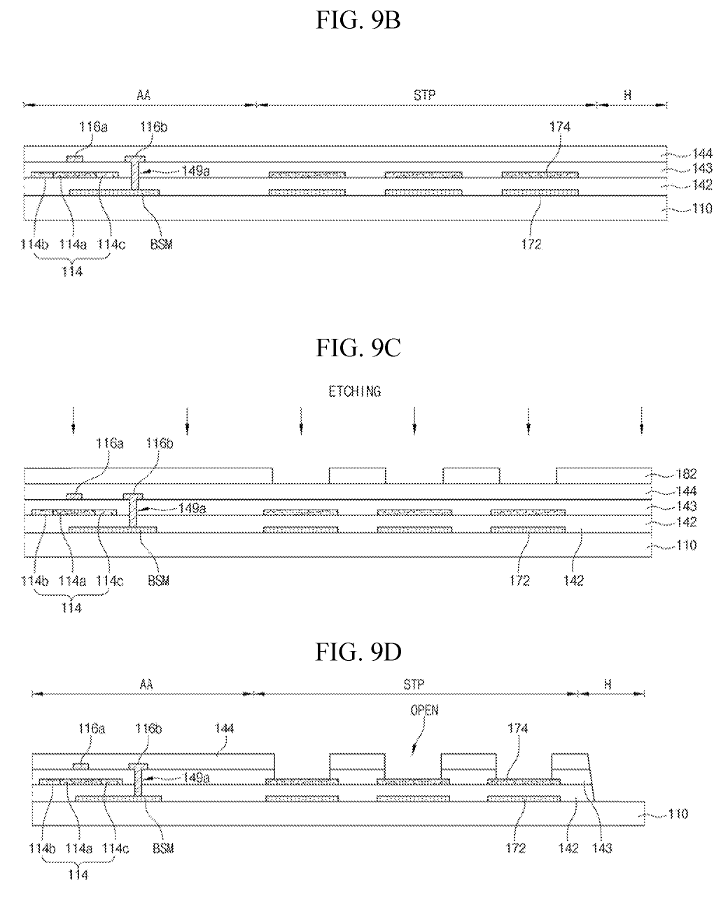

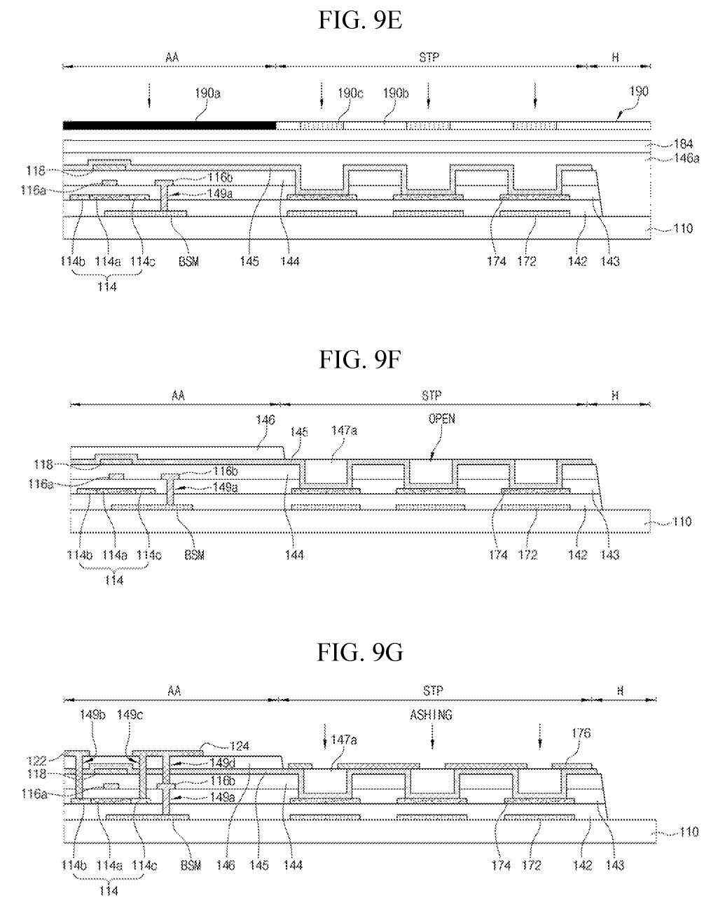

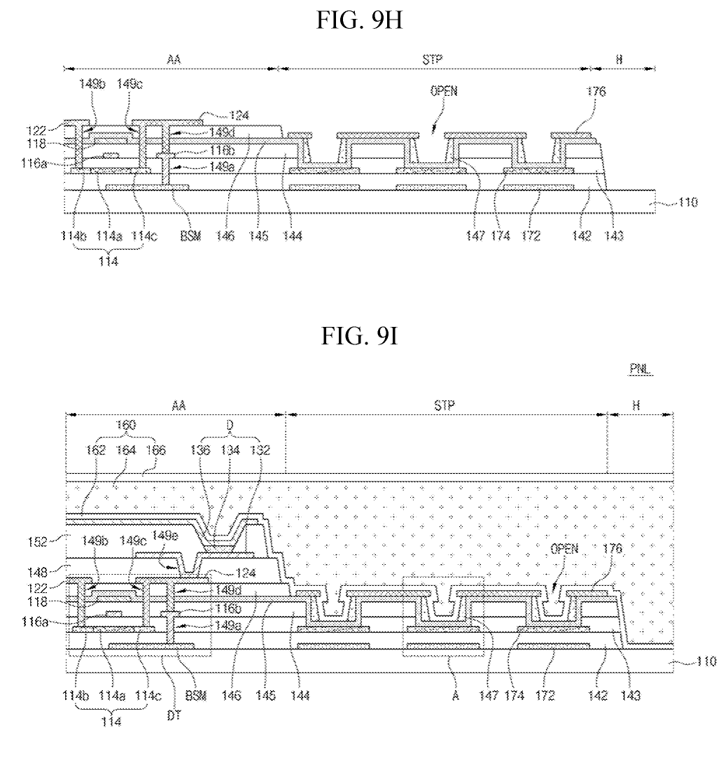

FIGS. 9A to 9I are views illustrating a method of manufacturing the display apparatus according to the present disclosure.

First, as shown in FIG. 9A, the metal is deposited in the entire area of the substrate 110 including the display area AA, the blocking unit STP, and the hole H and then etched to form the bottom shielding metal layer BSM in the display area AA and a plurality of first patterns 172 (or first etch blocking patterns) in the blocking unit STP. At this time, the substrate 110 may be made of a hard material such as glass and may be made of the plastic material such as a polyimide, a polymethylmethacrylate, a polyethylene tereththalate, a Polyethersulfone, and a Polycarbonate, but is not limited thereto.

Thereafter, the buffer layer 142 is formed by depositing at least one layer made of the insulating material such as SiOx or SiNx over the entire substrate 110.

Subsequently, the oxide semiconductors such as IGZO (Indium-galium-zinc-oxide), IZO (Indium-zinc-oxide), IGTO (Indium-galium-tin-oxide), and IGO (Indium-galium-oxide) are deposited on the buffer layer 142 and then etched to form the semiconductor layer 114 in the display area AA and the second pattern 174 (or the second etch-blocking pattern) in the blocking unit STP. Further, the impurities are doped on both sides of the semiconductor layer 114 to form the channel region 112a, the source region 112b, and the drain region 112c.

Thereafter, as shown in FIG. 9B, the inorganic material such as SiOx or SiNx is deposited over the entire substrate 110 to form the gate insulating layer 143, and then the metal such as molybdenum (Mo), aluminum (Al), chromium (Cr), gold (Au), titanium (Ti), nickel (Ni), neodymium (Nd), and copper (Cu) is deposited by sputtering process and etched to form the gate electrode 116a and the connection electrode 116b in the display area AA. In this case, the connection electrode 116b is connected to the bottom shielding metal layer BSM through the first contact hole 149a formed in the buffer layer 142 and the gate insulating layer 143.

Subsequently, the interlayer insulating layer 144 is formed on the gate insulating layer 143 on which the gate electrode 116a and the connection electrode 116b are disposed.

Subsequently, as shown in FIG. 9C, a photoresist is deposited on the interlayer insulating layer 144 and developed to form the first photoresist pattern 182.

Subsequently, using the first photoresist pattern 182 as a mask, the layers under the first photoresist pattern 182 are etched to remove the gate insulating layer 143 and the interlayer insulating layer 144 above the second pattern 174 in order to form a plurality of openings OPEN in the blocking unit STP, as shown in FIG. 9D. In this case, the gate insulating layer 143 and the interlayer insulating layer 144 of the hole H may be removed.

Thereafter, as shown in FIG. 9E, the metal is deposited on the interlayer insulating layer 144 and then etched to form the storage electrode 118 on the interlayer insulating layer 144 above the gate electrode 116a. In this case, the gate electrode 116a and the storage electrode 118 are disposed with the interlayer insulating layer 144 interposed therebetween to form the storage capacitor.

Subsequently, the inorganic insulating material such as SiOx or SiNx is deposited to form the passivation layer 145 on the interlayer insulating layer 144 and inside the opening OPEN.

Thereafter, the insulating layer 146a is deposited the entire substrate 110 and the photoresist is deposited thereon to form the photoresist layer 184, and then the UV rays are irradiated to the photoresist layer 184 using the photomask 190 to develop the photoresist layer 184.

In this case, the photomask 190 is a half tone mask or a diffraction mask. The photomask 190 includes a blocking portion 190a that blocks light, a semi-transmitting portion 190b that transmits only a part of light, and a transmitting portion 190c that transmits the entire light. In this case, the blocking portion 190a of the photomask layer 190 is located in the display area AA, the semi-transmitting portion 190b is located in the opening OPEN, and the transmitting portion 190cis located in the blocking unit STP and the hole H except for the opening OPEN.

As UV rays are irradiated using the photomask 190 to the photoresist layer 184 and then developed, the photoresist layer 184 becomes a photoresist pattern having different thicknesses. When the insulating layer 146a below photoresist pattern is etched using this photoresist pattern, the second planarization layer 146 is formed in the display area AA and the insulating pattern 147a is formed inside the opening OPEN, as shown in FIG. 9F.

In this case, the insulating layer 146a of the display area AA is not removed by etching, and thus the second planarization layer 146 is formed in the display area AA. A part of the insulating layer 146a is removed in the opening OPEN of the blocking unit STP to remain the insulating pattern 147a in the opening OPEN. The insulating layer 146a is completely removed in the area other than the opening OPEN of the blocking unit STP, so that the passivation layer 145 is exposed to the outside.

Subsequently, as shown in FIG. 9G, the metal is deposited and etched to form the source electrode 122 and the drain electrode 124 on the first planarization layer 146 of the display area AA, and to form the metal pattern 176 in the blocking unit. In this case, the metal pattern 176 protrudes toward the opening OPEN to form the overhang structure between the opening OPEN and the metal pattern 176.

Thereafter, when the insulating pattern 147a of the blocking unit STP is ashed, only the insulating material formed in the central area of the opening OPEN is removed by the metal pattern 176 of the overhang structure, and the insulating material on both sides of the opening OPEN is not removed. Therefore, as shown in FIG. 9H, the insulating pattern 147, which covers the sidewall of the opening OPEN and exposes the passivation layer 145 in the central area, is formed within the opening OPEN,.

Subsequently, as shown in FIG. 9I, the organic material such as photoacrylic or the inorganic material such as SiOx or SiNx is deposited to form the second planarization layer 148. Thereafter, the transparent metal oxide such as ITO or IZO, or the metal such as silver (AG), aluminum (Al), gold (Au), molybdenum (Mo), tungsten (W), or chromium (Cr) is deposited and etched to form the first electrode 132 on the second planarization layer 148. In this case, the first electrode 132 is electrically connected to the drain electrode 124 of the transistor DT through the fifth contact hole 149e formed in the second planarization layer 148.

Thereafter, at least one of the inorganic insulating materials such as SiNx or SiOx, the organic insulating materials such as BCB (BenzoCycloButene), acrylic resin, epoxy resin, phenolic resin, polyamide resin, polyimide resin, and the photoresist containing black pigments is deposited on the second planarization layer 148 and etched by dry etching method to form the bank layer BNK.

Subsequently, the light emitting material is coated to the display area AA to form the light emitting layer 134, and then the transparent metal oxide material such as ITO or IZO or the metal such as silver (AG), aluminum (Al), gold (Au), molybdenum (Mo), tungsten (W), and chromium (Cr) is deposited and etched to form the second electrode 136.

Thereafter, the first encapsulation layer 182 is formed by coating the inorganic material, the second encapsulation layer 184 is formed by coating the organic material on the first encapsulation layer 182, and the third encapsulation layer 186 is formed by coating the inorganic material on the second encapsulation layer 184 to complete the display apparatus 100.

In the method of manufacturing the display apparatus 100 according to the present disclosure, when the gate insulating layer 143 and the interlayer insulating layer 144 are etched to form the opening OPEN of the blocking unit STP, the first pattern 172 and the second pattern 174 are disposed to prevent the etching of the buffer layer 142 therebelow. When etching the gate insulating layer 143 and the interlayer insulating layer 144, etching of the buffer layer 142 may be prevented by using one of the first pattern 172 and the second pattern 174. However, when only the first pattern 172 is used, the second pattern 174 made of semiconductor material is easily etched by etching gas (or etching solution), so the buffer layer 142 under the second pattern 174 is also etched and thus the passivation layer 145 can be directly disposed on the substrate 110. Further, when only the second pattern 174 is used, the height of the opening OPEN is increased, so that the crack may be generated in the first encapsulation layer 162 formed inside the opening OPEN and thus the moisture may be penetrated into the display area through this crack. However, in this disclosure, the etching of the buffer layer 142 is prevented by using the first pattern 172 and the second pattern 174, so these problems can be prevented.

One or more example embodiments of the present disclosure will be described below.

According to one or more example embodiments of the present disclosure, the display apparatus, comprises: a substrate including a display area in which a plurality of sub-pixels are disposed to display an image, a hole formed in display area in which an optical sensor is mounted, and a blocking unit formed between the display area and the hole; a thin film transistor and a light emitting device disposed in each of sub-pixels; an opening formed in the blocking unit; a first pattern disposed under the opening; and a second pattern disposed between the opening and the first pattern.

According to one or more example embodiments of the present disclosure, the display apparatus, further comprises: a bottom shielding metal layer on the substrate in the display area under the thin film transistor.

According to one or more example embodiments of the present disclosure, the thin film transistor includes: a semiconductor layer on the buffer layer covering the bottom shielding metal layer; a gate insulating layer on the semiconductor layer; a gate electrode on the gate insulating layer; an interlayer insulating layer on the gate electrode; a passivation layer on the interlayer insulating layer; a first planarization layer on the passivation layer; a second planarization layer on the first planarization layer; and a source electrode and a drain electrode on the first planarization layer, the source electrode and the drain electrode being electrically connected to the semiconductor layer.

According to one or more example embodiments of the present disclosure, the first pattern is disposed on the substrate in the blocking unit.

According to one or more example embodiments of the present disclosure, the first pattern is made of the same material as the bottom shielding metal layer.

According to one or more example embodiments of the present disclosure, the second pattern is disposed above the buffer layer.

According to one or more example embodiments of the present disclosure, the second pattern is made of the same material as the semiconductor layer.

According to one or more example embodiments of the present disclosure, the display apparatus, further comprises: a metal pattern disposed on the passivation layer in the blocking unit, the metal pattern being protruded toward the opening to form an overhang structure with the opening.

According to one or more example embodiments of the present disclosure, the metal pattern is made of the same material as the source electrode and the drain electrode.

According to one or more example embodiments of the present disclosure, the display apparatus, further comprises: an insulating pattern disposed under the metal pattern within the opening.

According to one or more example embodiments of the present disclosure, the insulating pattern covers both sides of the opening.

According to one or more example embodiments of the present disclosure, the insulating pattern is made of the same material as the first planarization layer.

According to one or more example embodiments of the present disclosure, a width of the insulating pattern increases from a lower surface of the metal pattern to an upper surface of the passivation layer on a bottom of the opening.

According to one or more example embodiments of the present disclosure, the width of the insulating pattern disposed on the upper surface of the passivation layer on the bottom of the opening is smaller than a length of the metal pattern protruding from the opening.

According to one or more example embodiments of the present disclosure, a width of the first pattern and a width of the second pattern are the same.

According to one or more example embodiments of the present disclosure, a width of the first pattern is greater than a width of the second pattern.

According to one or more example embodiments of the present disclosure, a width of the opening is smaller than a width of the second pattern.

According to one or more example embodiments of the present disclosure, the blocking unit includes a plurality of the openings that are formed to be spaced apart from each other by a predetermined distance and are disposed along a periphery of the hole.

According to one or more example embodiments of the present disclosure, the display panel, comprises: a substrate including a display area in which a plurality of sub-pixels are disposed to display an image, a hole formed in display area in which an optical sensor is mounted, and a blocking unit formed between the display area and the hole; a thin film transistor and a light emitting device disposed in each of sub-pixels; an opening formed in the blocking unit; a first pattern disposed under the opening; and a second pattern disposed between the opening and the first pattern.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus, comprising:
a substrate including a display area in which a plurality of sub-pixels are disposed to display an image;
a hole in the display area, the hole configured to receive an optical sensor;
a blocking unit between the display area and the hole;
a thin film transistor and a light emitting device disposed in each of the sub-pixels of the plurality of sub-pixels;
an opening in the blocking unit;
a first pattern disposed under the opening; and
a second pattern disposed between the opening and the first pattern.

2. The display apparatus of claim 1, further comprising a bottom shielding metal layer on the substrate in the display area under the thin film transistor.

3. The display apparatus of claim 2, wherein the thin film transistor includes:
a buffer layer on the substrate;
a semiconductor layer on the buffer layer covering the bottom shielding metal layer;
a gate insulating layer on the semiconductor layer;
a gate electrode on the gate insulating layer;
an interlayer insulating layer on the gate electrode;
a passivation layer on the interlayer insulating layer;
a first planarization layer on the passivation layer;
a second planarization layer on the first planarization layer; and
a source electrode and a drain electrode on the first planarization layer, the source electrode and the drain electrode being electrically connected to the semiconductor layer.

4. The display apparatus of claim 3, wherein the first pattern is disposed on the substrate in the blocking unit.

5. The display apparatus of claim 4, wherein the first pattern is made of the same material as the bottom shielding metal layer.

6. The display apparatus of claim 3, wherein the second pattern is disposed above the buffer layer.

7. The display apparatus of claim 6, wherein the second pattern is made of the same material as the semiconductor layer.

8. The display apparatus of claim 3, further comprising a metal pattern disposed on the passivation layer in the blocking unit, the metal pattern protruding toward the opening such that a portion of the metal pattern overhangs the opening.

9. The display apparatus of claim 8, wherein the metal pattern is made of the same material as the source electrode and the drain electrode.

10. The display apparatus of claim 9, further comprising an insulating pattern disposed under the metal pattern within the opening.

11. The display apparatus of claim 10, wherein the insulating pattern covers both sides of the opening.

12. The display apparatus of claim 10, wherein the insulating pattern is made of the same material as the first planarization layer.

13. The display apparatus of claim 10, wherein a width of the insulating pattern increases from a lower surface of the metal pattern to an upper surface of the passivation layer on a bottom of the opening.

14. The display apparatus of claim 13, wherein the width of the insulating pattern disposed on the upper surface of the passivation layer on the bottom of the opening is smaller than a length of a portion of the metal pattern protruding from the opening.

15. The display apparatus of claim 1, wherein a width of the first pattern and a width of the second pattern are the same.

16. The display apparatus of claim 1, wherein a width of the first pattern is greater than a width of the second pattern.

17. The display apparatus of claim 1, wherein a width of the opening is smaller than a width of the second pattern.

18. The display apparatus of claim 1, wherein the blocking unit includes the opening that are formed to be spaced apart from each other by a distance and are disposed along a periphery of the hole.

19. A display panel, comprising:
a substrate including a display area in which a plurality of sub-pixels are disposed to display an image;
a hole in the display area, the hole configured to receive an optical sensor;
a blocking unit between the display area and the hole;
a thin film transistor and a light emitting device disposed in each of the sub-pixels of the plurality of sub-pixels;
an opening in the blocking unit;
a first pattern disposed under the opening; and
a second pattern disposed between the opening and the first pattern.

20. The display panel of claim 19, wherein the blocking unit includes the opening that are formed to be spaced apart from each other by a distance and are disposed along a periphery of the hole.
